(19) United States
(12) Patent Application Publication
(10) Pub. No.: US 2024/0247986 A1
(43) Pub. Date: Jul. 25, 2024

(54) SEALED FORCE SENSOR WITH ETCH STOP LAYER

(71) Applicant: NextInput, Inc., San Jose, CA (US)

(72) Inventors: Julius Minglin Tsai, San Jose, CA (US); Ryan Diestelhorst, Sunnyvale, CA (US); Dan Krstyen Benjamin, Marietta, GA (US)

(21) Appl. No.: 18/597,341

(22) Filed: Mar. 6, 2024

Related U.S. Application Data
(63) Continuation of application No. 17/860,941, filed on Jul. 8, 2022, now Pat. No. 11,965,787.
Application No. 17/860,941 is a continuation of application No. 16/761,373, filed on May 4, 2020, now Pat. No. 11,385,108.
(60) Provisional application No. 62/580,530, filed on Nov. 2, 2017.

(51) Int. Cl. G01L 1/18; B81B 3/00; B81C 1/00; G01L 1/26

(52) U.S. Cl. CPC G01L 1/18; B81B 3/0021; B81C 1/00595; G01L 1/26; B81B 2203/0127; B81C 2201/014

(57) ABSTRACT

An example microelectromechanical system (MEMS) force sensor is described herein. The MEMS force sensor can include a sensor die configured to receive an applied force. The sensor die can include a first substrate and a second substrate, where a cavity is formed in the first substrate and where at least a portion of the second substrate defines a deformable membrane. The MEMS force sensor can also include an etch stop layer arranged between the first substrate and the second substrate, and a sensing element arranged on a surface of the second substrate. The sensing element can be configured to convert a strain on the surface of the membrane substrate to an analog electrical signal that is proportional to the strain.

### RELATED APPLICATIONS

This application is a continuation of U.S. patent application Ser. No. 17/860,941, filed Jul. 8, 2022, which is a continuation of U.S. patent application Ser. No. 16/761,373, filed May 4, 2020, now U.S. Pat. No. 11,385,108, which is a national phase filing of International Application No. PCT/US2018/058928, filed Nov. 2, 2017, which claims the benefit of provisional patent application Ser. No. 62/580,530, filed Nov. 2, 2017, the disclosures of which are hereby incorporated herein by reference in their entirety.

### FIELD OF THE DISCLOSURE

The present disclosure relates to a microelectromechanical system (MEMS) sensor for force sensing, including an etch stop layer for precise membrane thickness control.

### BACKGROUND

Microelectromechanical system (MEMS) force sensors are typically designed with a membrane that deforms with applied force. Deformation of the membrane mechanically amplifies the stress induced by the load. The sensitivity of the MEMS force sensor is mainly dominated by the thickness of the membrane. Thinner membranes cause the sensitivity to increase, while thicker membranes cause the sensitivity to decrease. When membrane thickness is controlled through the etch process, there is still a large variation in sensitivity, e.g., in the range of 10% to 20%. On the other hand, other processes such as grinding and polishing of the membrane can produce much better tolerances, e.g., in the range of less than 5%.

### SUMMARY

In one implementation, the present disclosure pertains to an etch stop layer performed before the cavity etch. The membrane thickness is precisely controlled by the thickness of the silicon layer during grinding/polishing, epi-growth, or other deposition methods. The etch stop layer then absorbs all the etch non-uniformity during the cavity etch due to the larger etch ratio between the silicon and the etch layer. The etch stop layer can later be selectively removed, leaving only silicon as the membrane material. Mesas can also be selectively formed on the membrane sealed inside the cavity for overload protection.

An example microelectromechanical system (MEMS) force sensor is described herein. The MEMS force sensor can include a sensor die configured to receive an applied force. The sensor die can include a first substrate and a second substrate, where a cavity is formed in the first substrate and where at least a portion of the second substrate defines a deformable membrane. The MEMS force sensor can also include an etch stop layer arranged between the first substrate and the second substrate, and a sensing element arranged on a surface of the second substrate. The sensing element can be configured to convert a strain on the surface of the membrane substrate to an analog electrical signal that is proportional to the strain.

Additionally, the etch stop layer can be configured for precise thickness control of the deformable membrane of the membrane substrate. For example, an etch rate of the etch stop layer can be different than an etch rate of the first substrate. Optionally, an etch rate ratio between the etch rate of the first substrate and the etch rate of the etch stop layer can be between 50 and 150.

Alternatively, or additionally, the MEMS force sensor can further include a protective layer arranged on the surface of the second substrate, and a conductive pad arranged on the protective layer. The sensing element can be electrically coupled to the conductive pad, where the protective layer at least partially covers one or more of the sensing elements, the surface of the second substrate, and the conductive pad.

In some implementations, the MEMS force sensor can further include an under bump metal (UBM) layer and a solder bump, where the MEMS force sensor is mounted on a package substrate using the UBM layer and the solder bump. Optionally, the conductive pad, the UBM layer, and the solder bump can be fully overlapping with a mesa formed from the first substrate. Alternatively, the conductive pad, the UBM layer, and the solder bump cannot be overlapping with a mesa formed from the first substrate or the deformable membrane defined by the second substrate.

Alternatively, or additionally, the conductive pad can be electrically coupled to the package substrate through the UBM layer and the solder bump.

Alternatively, or additionally, the package substrate can be a printed circuit board (PCB) or a flexible printed circuit board (FPCB).

Alternatively, or additionally, the MEMS force sensor can further include a mesa formed from the first substrate.

Alternatively, or additionally, the etch stop layer can cover the deformable membrane of the membrane substrate.

Alternatively, or additionally, the etch stop layer can be removed from the deformable membrane of the membrane substrate.

Alternatively, or additionally, the etch stop layer can be composed of silicon dioxide, silicon nitride, or sapphire.

Alternatively, or additionally, the MEMS force sensor can further include a plurality of sensing elements arranged on the surface of the second substrate.

Alternatively, or additionally, the sensing element can be a piezoresistive or piezoelectric sensing element.

Alternatively, or additionally, the MEMS force sensor can further include a cap substrate, wherein the cap substrate is bonded to the first substrate, and wherein the cavity is sealed between the cap substrate and the first substrate.

An example method of manufacturing a MEMS force sensor is also described herein. The method can include providing a first substrate, a second substrate, and an etch stop layer, where the etch stop layer is arranged between the first and second substrates, and where a sensing element is arranged on a surface of the second substrate. The method can also include etching the first substrate, where the etch process removes a portion of the first substrate to form a cavity in the first substrate.

Additionally, the etch process can remove a portion of the etch stop layer. Alternatively, the etch process does not remove a portion of the second substrate.

Alternatively, or additionally, the etch stop layer can be configured for precise thickness control of the deformable membrane of the membrane substrate. For example, an etch rate of the etch stop layer can be different than an etch rate of the first substrate. Optionally, an etch rate ratio between the etch rate of the first substrate and the etch rate of the etch stop layer can be between 50 and 150.

Alternatively, or additionally, the etch process can further form a mesa in the first substrate.

Alternatively, or additionally, the method can further include bonding a cap substrate to the first substrate, where the cavity is sealed between the cap substrate and the first substrate.

Alternatively, or additionally, the method can further include providing a protective layer arranged on the surface of the second substrate, and providing a conductive pad arranged on the protective layer, where the sensing element is electrically coupled to the conductive pad, and where the protective layer at least partially covers one or more of the sensing elements, the surface of the second substrate, and the conductive pad.

Alternatively, or additionally, the method can further include providing a UBM layer and a solder bump, where the UBM layer is arranged on the conductive pad and the solder bump is arranged on the UBM layer.

Alternatively, or additionally, the method can further include bonding the MEMS force sensor to a package substrate, where the MEMS force sensor is mounted on the package substrate using the UBM layer and the solder bump. The package substrate can be a PCB or a FPCB.

Alternatively, or additionally, the sensing element can be formed using an implant or deposition process.

Alternatively, or additionally, the sensing element can be at least one of a piezoresistive or piezoelectric sensing element.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWING FIGURES

The components in the drawings are not necessarily to scale relative to each other. Like reference numerals designate corresponding parts throughout the several views. These and other features of will become more apparent in the detailed description in which reference is made to the appended drawings wherein:

FIG. 1 illustrates an example microelectromechanical system (MEMS) force sensor with a sealed cavity and an etch stop layer;

FIG. 2 illustrates another example MEMS force sensor with a sealed cavity, an etch stop layer, and a mesa sealed inside the cavity;

FIG. 3 illustrates another example MEMS force sensor with a sealed cavity, an etch stop layer, and a mesa sealed inside the cavity;

FIG. 4 illustrates an example MEMS force sensor mounted on a package substrate through solder bumps, where the solder bumps do not overlap with the membrane or the mesa of the MEMS force sensor; and

FIG. 5 illustrates another example MEMS force sensor mounted on a package substrate through solder bumps, where the solder bumps fully overlap with the mesa of the MEMS force sensor.

### DETAILED DESCRIPTION

The present disclosure can be understood more readily by reference to the following detailed description, examples, drawings, and their previous and following description. However, before the present devices, systems, and/or methods are disclosed and described, it is to be understood that this disclosure is not limited to the specific devices, systems, and/or methods disclosed unless otherwise specified, and, as such, can, of course, vary. It is also to be understood that the terminology used herein is for the purpose of describing particular aspects only and is not intended to be limiting.

The following description is provided as an enabling teaching. To this end, those skilled in the relevant art will recognize and appreciate that many changes can be made, while still obtaining beneficial results. It will also be apparent that some of the desired benefits can be obtained by selecting some of the features without utilizing other features. Accordingly, those who work in the art will recognize that many modifications and adaptations may be possible and can even be desirable in certain circumstances, and are contemplated by this disclosure. Thus, the following description is provided as illustrative of the principles and not in limitation thereof.

As used throughout, the singular forms “a,” “an,” and “the” include plural referents unless the context clearly dictates otherwise. Thus, for example, reference to “a sensing element” can include two or more such sensing elements unless the context indicates otherwise.

The term “comprising” and variations thereof as used herein is used synonymously with the term “including” and variations thereof and are open, non-limiting terms.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

As used herein, the terms “optional” or “optionally” mean that the subsequently described event or circumstance may or may not occur, and that the description includes instances where said event or circumstance occurs and instances where it does not.

The present disclosure relates to an etch stop layer for precise membrane thickness control and the package implementation for a force sensor.

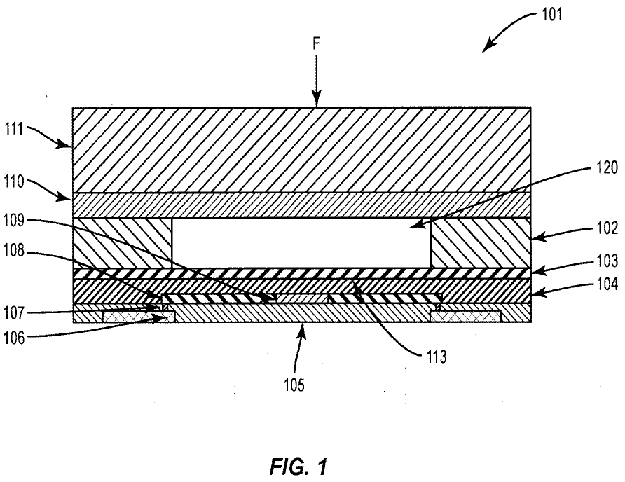

Referring now to FIG. 1, a microelectromechanical system (MEMS) force sensor 101, according to one example implementation, is shown. The MEMS force sensor 101 can include a cavity substrate 102 (also referred to herein as a “first substrate”) bonded to a membrane substrate 104 (also referred to herein as a “second substrate”) through an etch stop layer 103. As described herein, at least a portion of the membrane substrate 104 forms a deformable membrane 113. A cavity 120 is etched from the cavity substrate 102. This disclosure contemplates using etching techniques known in the art to form the cavity. For example, etching processes include, but are not limited to, silicon deep reactive etch (DRIE), normal reactive etch (RIE), wet chemical etching using potassium hydroxide (KOH), or tetramethylammonium hydroxide (TMAH), all of which can be used to form the cavity. As shown in FIG. 1, the etch is stopped on the etch stop layer 103. The etch does not extend through the etch stop layer 103 and, therefore, does not reach the membrane substrate 104. The etch process is well controlled by the etch rate ratio between the respective materials of the cavity substrate 102 (e.g., silicon) and the etch stop layer 103 (e.g., silicon dioxide). For example, the etch rate ratio between an etch rate of the material of the cavity substrate 102 (e.g., silicon) and an etch rate of the material of the etch stop layer 103 can optionally be in the range from 50 to 150. In some implementations, the etch rate ratio is greater than or equal to 50. In some implementations, the etch rate ratio is greater than or equal to 60. In some implementations, the etch rate ratio is greater than or equal to 70. In some implementations, the etch rate ratio is greater than or equal to 80. In some implementations, the etch rate ratio is greater than or equal to 90. In some implementations, the etch rate ratio is greater than or equal to 100. In some implementations, the etch rate ratio is greater than or equal to 110. In some implementations, the etch rate ratio is greater than or equal to 120. In some implementations, the etch rate ratio is greater than or equal to 130. In some implementations, the etch rate ratio is greater than or equal to 140. In some implementations, the etch rate ratio is greater than or equal to 150. This disclosure contemplates using materials other than those provided as examples, such as gallium arsenide (GaAs) or silicon carbide (SiC) for the cavity substrate 102 and/or silicon nitride or sapphire for the etch stop layer 103. It should be understood that the cavity substrate and etch stop layer materials listed above are only provided as examples, and that other materials can be used.

The thickness of the deformable membrane 113, which is formed from the membrane substrate 104, can, therefore, be precisely controlled. This thickness can be precisely controlled with the processes used to fabricate the membrane substrate 104, e.g., semiconductor deposition, epitaxial growth, and/or grinding/polishing, etc. The etch stop layer 103 can absorb any non-uniformity introduced by the etch process used to form the cavity 120 in the cavity substrate 102. As discussed above, the thickness of the deformable membrane 113 affects sensitivity of the MEMS force sensor 101. Thus, by precisely controlling the deformable membrane thickness using the etch stop layer 103 to stop the etch process, it is possible to precisely control the sensitivity of the MEMS force sensor 101. The membrane substrate 104 is not etched, so the thickness of the membrane substrate 104 is not affected by the etch process. This is in contrast to the case where the deformable membrane is formed from the same substrate from which the cavity and/or mesa is formed (e.g., etched). Examples of MEMS force sensors where the deformable membrane is formed by etching a sensor substrate are described in U.S. Pat. No. 9,487,388, issued Nov. 8, 2016 and entitled “Ruggedized MEMS Force Die;” U.S. Pat. No. 9,493,342, issued Nov. 15, 2016 and entitled “Wafer Level MEMS Force Dies;” U.S. Pat. No. 9,902,611, issued Feb. 27, 2018 and entitled “Miniaturized and Ruggedized Wafer Level MEMS Force Sensors;” and U.S. Pat. No. 10,466,119, issued Nov. 5, 2019 and entitled “Ruggedized Wafer Level MEMS Force Sensor with a Tolerance Trench,” the disclosures of which are incorporated by reference in their entireties. In other words, the deformable membrane 113 is formed from a different substrate (e.g., the membrane substrate 104) than the substrate etched to form the cavity (e.g., the cavity substrate 102).

The MEMS force sensor 101 can include a cap substrate 111. The cap substrate 111 can be formed of a glass (e.g., borosilicate glass) or a silicon. Although glass and silicon are provided as example materials, it should be understood that the cap substrate 111 can be made of other suitable materials. The cap substrate 111 can be bonded to the cavity substrate 102 using techniques known in the art that are including, but not limited to, silicon fusion bonding, anodic bonding, glass frit, thermo-compression, and eutectic bonding. For example, as shown in FIG. 1, the cavity substrate 102 is bonded to the cap substrate 111 through a bond layer 110. This disclosure contemplates that the bond layer 110 can optionally be formed of a silicon oxide. As described below, the cavity 120 is sealed between the cavity substrate 102 and the cap substrate 111. Thus, a volume enclosed by the cap substrate 111 and the cavity substrate 102 is sealed from an environment external to the MEMS force sensor 101. The cavity 120 is formed by removing (e.g., by etch process) portions of the cavity substrate 102 and/or the etch stop layer 103 and sealing the volume between the cap substrate 111 and the cavity substrate 102. Example MEMS force sensors that have a sealed cavity are described in U.S. Pat. No. 9,902,611, issued Feb. 27, 2018 and entitled “Miniaturized and Ruggedized Wafer Level MEMS Force Sensors;” and U.S. Pat. No. 10,466,119, issued Nov. 5, 2019 and entitled “Ruggedized Wafer Level MEMS Force Sensor with a Tolerance Trench,” the disclosures of which are incorporated by reference in their entireties.

The MEMS force sensor 101 can also include a sensing element 109. As shown in FIG. 1, the sensing element 109 can be disposed on a surface of the membrane substrate 104, e.g., on the deformable membrane 113. Optionally, in some implementations, the MEMS force sensor 101 can include a plurality of sensing elements 109 disposed on a surface of the membrane substrate 104. This disclosure contemplates that the sensing element(s) 109 can be diffused, deposited, or implanted on a surface of the membrane substrate 104. The sensing element 109 can change an electrical characteristic (e.g., resistance, capacitance, charge, etc.) in response to a deflection of the deformable membrane 113. In one implementation, the sensing element 109 can optionally be a piezoresistive transducer. Although piezoresistive transducers are provided as an example sensing element, this disclosure contemplates that the sensing element 109 can be any sensing element configured to change at least one electrical characteristic (e.g., resistance, charge, capacitance, etc.) based on an amount or magnitude of an applied force and can output a signal proportional to the amount or magnitude of the applied force. Other types of sensing elements include, but are not limited to, piezoelectric or capacitive sensors.

As discussed above, the sensing element 109 can, optionally, be a piezoresistive transducer. The change in the electrical characteristic can be measured as an analog electrical signal and, optionally, received at and processed by digital circuitry (e.g., CMOS circuitry). For example, as strain is induced in the deformable membrane 113 proportional to a force “F” applied to the MEMS force sensor 101, a localized strain is produced on the piezoresistive transducer such that the piezoresistive transducer experiences compression or tension, depending on its specific orientation. As the piezoresistive transducer compresses and tenses, its resistivity changes in an opposite fashion. Accordingly, a Wheatstone bridge circuit including a plurality (e.g., four) of piezoresistive transducers (e.g., two of each orientation relative to strain) becomes unbalanced and produces a differential voltage across the positive signal terminal and the negative signal terminal. This differential voltage is directly proportional to the applied force “F” on the MEMS force sensor 101. Example MEMS force sensors using piezoresistive sensing elements are described in U.S. Pat. No. 9,487,388, issued Nov. 8, 2016 and entitled “Ruggedized MEMS Force Die;” U.S. Pat. No. 9,493,342, issued Nov. 15, 2016 and entitled “Wafer Level MEMS Force Dies;” U.S. Pat. No. 9,902,611, issued Feb. 27, 2018 and entitled “Miniaturized and Ruggedized Wafer Level MEMS Force Sensors;” and U.S. Pat. No. 10,466,119, issued Nov. 5, 2019 and entitled “Ruggedized Wafer Level MEMS Force Sensor with a Tolerance Trench,” the disclosures of which are incorporated by reference in their entireties.

The MEMS force sensor 101 can also include an electrical connection 108, a conductive via 107, and a conductive pad 106 for routing the analog electrical signal produced by the sensing element 109. In FIG. 1, two electrical connections, two conductive vias, and two conductive pads are shown as providing electrical connection to the sensing element 109. It should be understood that the number and/or arrangement of the electrical connection 108, the conductive via 107, and the conductive pad 106 in FIG. 1 are provided only as examples. As shown in FIG. 1, the electrical connection 108, the conductive via 107, and the conductive pad 106 can be provided on the membrane substrate 104. The electrical connection 108, the conductive via 107, and the conductive pad 106 can be made of any suitable conductive material, including, but not limited to, aluminum, copper, or gold, for example. Additionally, the electrical connection 108, the conductive via 107, and the conductive pad 106 can be covered by a protective layer 105. The protective layer 105 can be made of any suitable dielectric material. As shown in FIG. 1, the protective layer 105 is provided on the surface of the membrane substrate 104, and the conductive pad 106 is provided on the protective layer 105. Additionally, the protective layer 105 can be partially opened on conductive pad 106. The electrical connection 108 and the conductive via 107 are used to electrically couple the sensing element 109 to the conductive pad 106. This facilitates the ability to mount the MEMS force sensor 101 to another circuit or substrate, such as a package substrate.

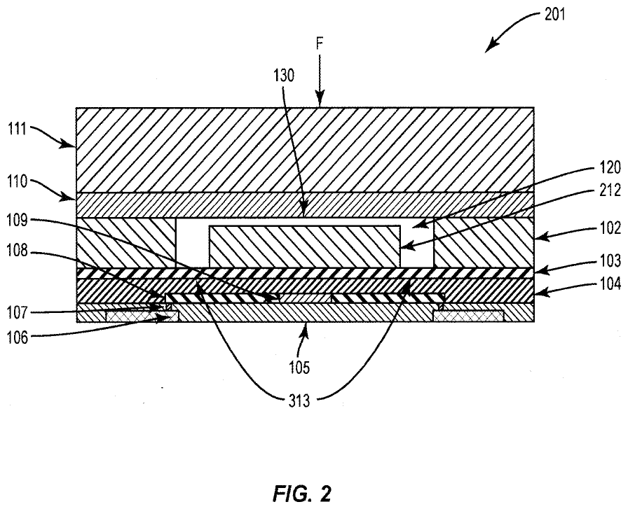

Referring now to FIG. 2, a MEMS force sensor 201, according to another example implementation, is shown. The MEMS force sensor 201 can include a cavity substrate 102 (also referred to herein as a “first substrate”) bonded to a membrane substrate 104 (also referred to herein as a “second substrate”) through an etch stop layer 103. As described herein, at least a portion of the membrane substrate 104 forms a deformable membrane 313. A cavity 120 is etched from the cavity substrate 102. Unlike the MEMS force sensor shown in FIG. 1, a mesa 212 is also formed during the etch process. The mesa 212 is used to transfer the force applied to the MEMS force sensor 201 to the deformable membrane 313. Additionally, a gap 130 (e.g., a space) is disposed between the mesa 212 and a cap substrate 111. The gap 130 can be formed during the etch process discussed above. The mesa 212 and/or the gap 130 provide overload protection for the MEMS force sensor 201. Examples of MEMS force sensors that are designed to provide overload protection are described in U.S. Pat. No. 9,487,388, issued Nov. 8, 2016 and entitled “Ruggedized MEMS Force Die;” U.S. Pat. No. 9,493,342, issued Nov. 15, 2016 and entitled “Wafer Level MEMS Force Dies;” U.S. Pat. No. 9,902,611, issued Feb. 27, 2018 and entitled “Miniaturized and Ruggedized Wafer Level MEMS Force Sensors;” and U.S. Pat. No. 10,466,119, issued Nov. 5, 2019 and entitled “Ruggedized Wafer Level MEMS Force Sensor with a Tolerance Trench,” the disclosures of which are incorporated by reference in their entireties. This disclosure contemplates using etching techniques known in the art to form the cavity, mesa, and/or gap. For example, etching processes include, but are not limited to, silicon DRIE, normal RIE, wet chemical etching using KOH, or TMAH, all of which can be used to form the cavity, mesa, and/or gap. As shown in FIG. 2, the etch is stopped on an etch stop layer 103. The etch does not extend through the etch stop layer 103 and, therefore, does not reach the membrane substrate 104. The etch process is well controlled by the etch rate ratio between the respective materials of the cavity substrate 102 (e.g., silicon) and the etch stop layer 103 (e.g., silicon dioxide). For example, the etch rate ratio between an etch rate of the material of the cavity substrate 102 (e.g., silicon) and an etch rate of the material of the etch stop layer 103 can, optionally, be in the range from 50 to 150. In some implementations, the etch rate ratio is greater than or equal to 50. In some implementations, the etch rate ratio is greater than or equal to 60. In some implementations, the etch rate ratio is greater than or equal to 70. In some implementations, the etch rate ratio is greater than or equal to 80. In some implementations, the etch rate ratio is greater than or equal to 90. In some implementations, the etch rate ratio is greater than or equal to 100. In some implementations, the etch rate ratio is greater than or equal to 110. In some implementations, the etch rate ratio is greater than or equal to 120. In some implementations, the etch rate ratio is greater than or equal to 130. In some implementations, the etch rate ratio is greater than or equal to 140. In some implementations, the etch rate ratio is greater than or equal to 150. This disclosure contemplates using materials other than those provided as examples, such as GaAs or SiC for the cavity substrate 102 and/or silicon nitride or sapphire for the etch stop layer 103. As discussed above, the thickness of the deformable membrane 313, which is formed from the membrane substrate 104, can, therefore, be precisely controlled. In particular, the thickness can be precisely controlled with the processes used to fabricate the membrane substrate 104, and the etch stop layer 103 can absorb any non-uniformity introduced by the etch process used to form the cavity, mesa, and/or gap from the cavity substrate 102. And, by precisely controlling deformable membrane thickness using the etch stop layer 103 to stop the etch process, it is possible to precisely control sensitivity of the MEMS force sensor 201.

The MEMS force sensor 201 can include the cap substrate 111. The cap substrate 111 can be bonded to the cavity substrate 102 using techniques known in the art including, but not limited to, silicon fusion bonding, anodic bonding, glass frit, thermo-compression, and eutectic bonding. For example, as shown in FIG. 2, the cavity substrate 102 is bonded to the cap substrate 111 through a bond layer 110. This disclosure contemplates that the bond layer 110 can, optionally, be formed of a silicon oxide. The cavity 120 is sealed between the cavity substrate 102 and the cap substrate 111, as described herein. Thus, a volume enclosed by the cap substrate 111 and the cavity substrate 102 is sealed from an environment external to the MEMS force sensor 201.

The MEMS force sensor 201 can also include a sensing element 109. As shown in FIG. 2, the sensing element 109 can be disposed on a surface of the membrane substrate 104. Optionally, in some implementations, the MEMS force sensor 201 can include a plurality of sensing elements 109 disposed on a surface of the membrane substrate 104. This disclosure contemplates that the sensing element(s) 109 can be diffused, deposited, or implanted on a surface of the membrane substrate 104. The sensing element 109 can change an electrical characteristic (e.g., resistance, capacitance, charge, etc.) in response to deflection of the deformable membrane 313. In one implementation, the sensing element 109 can, optionally, be a piezoresistive transducer. Although piezoresistive transducers are provided as an example sensing element, this disclosure contemplates that the sensing element 109 can be any sensing element configured to change at least one electrical characteristic (e.g., resistance, charge, capacitance, etc.) based on an amount or magnitude of an applied force and can output a signal proportional to the amount or magnitude of the applied force. Other types of sensing elements include, but are not limited to, piezoelectric or capacitive sensors.

The MEMS force sensor 201 can also include an electrical connection 108, a conductive via 107, and a conductive pad 106 for routing the analog electrical signal produced by the sensing element 109. In FIG. 2, two electrical connections, two conductive vias, and two conductive pads are shown for providing an electrical connection to the sensing element 109. It should be understood that the number and/or arrangement of the electrical connection 108, the conductive via 107, and the conductive pad 106 in FIG. 2 are provided only as examples. As shown in FIG. 2, the electrical connection 108, the conductive via 107, and the conductive pad 106 can be provided on the membrane substrate 104. The electrical connection 108, the conductive via 107, and the conductive pad 106 can be made of any suitable conductive material, including, but not limited to, aluminum, copper, or gold, for example. Additionally, the electrical connection 108, the conductive via 107, and the conductive pad 106 can be covered by a protective layer 105. The protective layer 105 can be made of any suitable dielectric material. As shown in FIG. 2, the protective layer 105 is provided on the surface of the membrane substrate 104, and the conductive pad 106 is provided on the protective layer 105. Additionally, the protective layer 105 can be partially opened on conductive pad 106. The electrical connection 108 and the conductive via 107 are used to electrically couple the sensing element 109 to the conductive pad 106. This facilitates the ability to mount the MEMS force sensor 201 to another circuit or substrate, such as a package substrate.

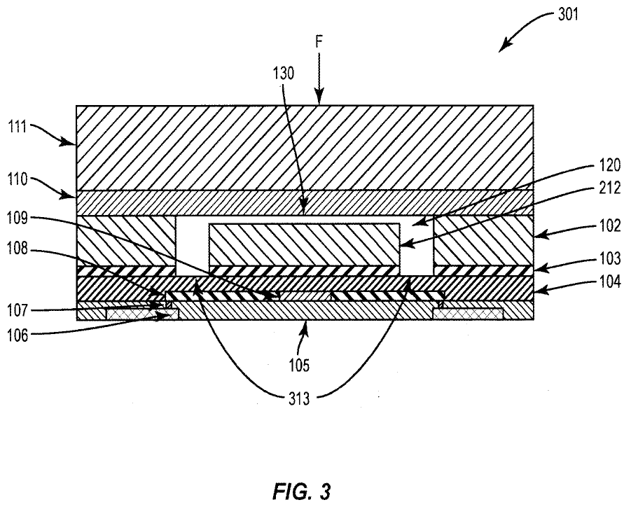

Referring now to FIG. 3, a MEMS force sensor 301, according to yet another example implementation, is shown. The MEMS force sensor 301 can include a cavity substrate 102 (also referred to herein as a “first substrate”) bonded to a membrane substrate 104 (also referred to herein as a “second substrate”) through an etch stop layer 103. As described herein, at least a portion of the membrane substrate 104 forms a deformable membrane 313. A cavity 120 is etched from the cavity substrate 102. Unlike the MEMS force sensor shown in FIG. 1, a mesa 212 is also formed during the etch process. The mesa 212 is used to transfer the force applied to the MEMS force sensor 301 to the deformable membrane 313. Additionally, a gap 130 (e.g., a space) is disposed between the mesa 212 and cap substrate 111. The gap 130 can be formed during the etch process discussed above. The mesa 212 and/or the gap 130 provide(s) overload protection for the MEMS force sensor 301. This disclosure contemplates using etching techniques known in the art to form the cavity, mesa, and/or gap. For example, etching processes include, but are not limited to, silicon DRIE, normal RIE, wet chemical etching using KOH, or TMAH, all of which can be used to form the cavity, mesa, and/or gap. Similarly to FIG. 1 and FIG. 2, the etch can be stopped on an etch stop layer 103. The etch does not extend through the etch stop layer 103 and, therefore, does not reach the membrane substrate 104. The etch process is well controlled by the etch rate ratio between the respective materials of the cavity substrate 102 (e.g., silicon) and the etch stop layer 103 (e.g., silicon dioxide). For example, the etch rate ratio between an etch rate of the material of the cavity substrate 102 (e.g., silicon) and an etch rate of the material of the etch stop layer 103 can optionally be in the range from 50 to 150. In some implementations, the etch rate ratio is greater than or equal to 60. In some implementations, the etch rate ratio is greater than or equal to 70. In some implementations, the etch rate ratio is greater than or equal to 80. In some implementations, the etch rate ratio is greater than or equal to 90. In some implementations, the etch rate ratio is greater than or equal to 100. In some implementations, the etch rate ratio is greater than or equal to 110. In some implementations, the etch rate ratio is greater than or equal to 120. In some implementations, the etch rate ratio is greater than or equal to 130. In some implementations, the etch rate ratio is greater than or equal to 140. In some implementations, the etch rate ratio is greater than or equal to 150. This disclosure contemplates using materials other than those provided as examples such as GaAs or SiC for the cavity substrate 102 and/or silicon nitride or sapphire for the etch stop layer 103. As discussed above, the thickness of the deformable membrane 313, which is formed from the membrane substrate 104, can, therefore, be precisely controlled. In particular, the thickness can be precisely controlled with the processes used to fabricate the membrane substrate 104, and the etch stop layer 103 can absorb any non-uniformity introduced by the etch process used to form the cavity, mesa, and/or gap from the cavity substrate 102. And, by precisely controlling deformable membrane thickness using the etch stop layer 103 to stop the etch process, it is possible to precisely control the sensitivity of the MEMS force sensor 301.

As shown in FIG. 3, portions of the etch stop layer 103 covering the deformable membrane 313 can be removed after forming the cavity, mesa, and/or gap. In FIG. 3, these portions correspond to regions of the membrane substrate 104 disposed about the mesa 212. This disclosure contemplates removing portions of the etch stop layer 103 by using an etch process. By removing portions of the etch stop layer 103, the thickness of the deformable membrane 313 can be further precisely controlled. In other words, the deformable membrane 313 is the only material left in the regions where the etch stop layer 103 has been removed. As discussed above, the thickness of the deformable membrane affects sensitivity of the MEMS force sensor 301, so removing portions of the etch stop layer 103, which adds material and thickness, facilitates controlling sensitivity.

The MEMS force sensor 301 can include a cap substrate 111. The cap substrate 111 can be bonded to the cavity substrate 102 using techniques known in the art including, but not limited to, silicon fusion bonding, anodic bonding, glass frit, thermo-compression, and eutectic bonding. For example, as shown in FIG. 3, the cavity substrate 102 is bonded to the cap substrate 111 through a bond layer 110. This disclosure contemplates that the bond layer 110 can, optionally, be formed of a silicon oxide. The cavity 120 is sealed between the cavity substrate 102 and the cap substrate 111, as described herein. Thus, a volume enclosed by the cap substrate 111 and the cavity substrate 102 is sealed from an environment external to the MEMS force sensor 301.

The MEMS force sensor 301 can also include a sensing element 109. As shown in FIG. 3, the sensing element 109 can be disposed on a surface of the membrane substrate 104. Optionally, in some implementations, the MEMS force sensor 301 can include a plurality of sensing elements 109 disposed on a surface of the membrane substrate 104. This disclosure contemplates that the sensing element(s) 109 can be diffused, deposited, or implanted on a surface of the membrane substrate 104. The sensing element 109 can change an electrical characteristic (e.g., resistance, capacitance, charge, etc.) in response to the deflection of the deformable membrane 313. In one implementation, the sensing element 109 can optionally be a piezoresistive transducer. Although piezoresistive transducers are provided as an example sensing element, this disclosure contemplates that the sensing element 109 can be any sensor element configured to change at least one electrical characteristic (e.g., resistance, charge, capacitance, etc.) based on an amount or magnitude of an applied force and can output a signal proportional to the amount or magnitude of the applied force. Other types of sensing elements include, but are not limited to, piezoelectric or capacitive sensors.

The MEMS force sensor 301 can also include an electrical connection 108, a conductive via 107, and a conductive pad 106 for routing the analog electrical signal produced by the sensing element 109. In FIG. 3, two electrical connections, two conductive vias, and two conductive pads are shown for providing electrical connection to the sensing element 109. It should be understood that the number and/or arrangement of the electrical connection 108, the conductive via 107, and the conductive pad 106 in FIG. 3 are provided only as examples. As shown in FIG. 3, the electrical connection 108, the conductive via 107, and the conductive pad 106 can be provided on the membrane substrate 104. The electrical connection 108, the conductive via 107, and the conductive pad 106 can be made of any suitable conductive material, including, but not limited to, aluminum, copper, or gold, for example. Additionally, the electrical connection 108, the conductive via 107, and the conductive pad 106 can be covered by a protective layer 105. The protective layer 105 can be made of any suitable dielectric material. As shown in FIG. 2, the protective layer 105 is provided on the surface of the membrane substrate 104, and the conductive pad 106 is provided on the protective layer 105. Additionally, the protective layer 105 can be partially opened on conductive pad 106. The electrical connection 108 and the conductive via 107 are used to electrically couple the sensing element 109 to the conductive pad 106. This facilitates the ability to mount the MEMS force sensor 301 to another circuit or substrate, such as a package substrate.

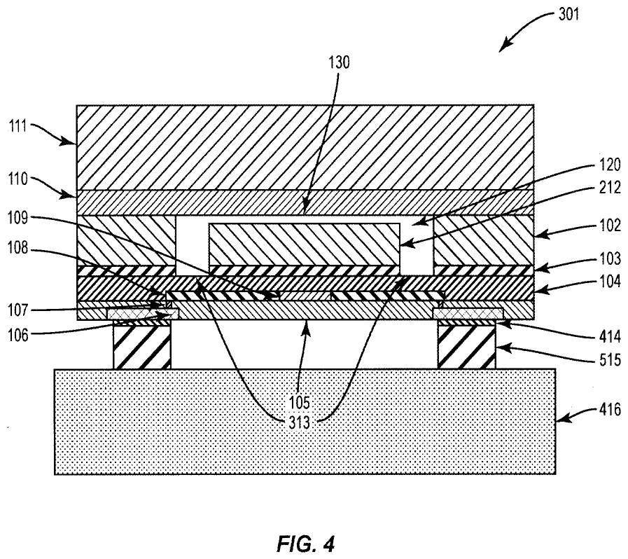

Referring now to FIG. 4, an example MEMS force sensor 301 mounted on a package substrate 416 through solder bumps, where the solder bumps do not overlap with the membrane or the mesa of the MEMS force sensor 301, is shown. The MEMS force sensor 301 is described in detail above with reference to FIG. 3. It should be understood that the MEMS force sensors shown in FIG. 1 and FIG. 2 can be mounted on a package substrate as described herein. In other words, the MEMS force sensor 301 is used only as an example in FIG. 4.

As shown in FIG. 4, an under bump metal (UBM) layer 414 can be formed on each of the conductive pads 106. This disclosure contemplates that the UBM layer 414 can be made of any suitable conductive material, including, but not limited to, aluminum, copper, or gold, for example. The UBM layer 414 is formed in the opening of the protective layer 105 that exposes the conductive pads 106. Additionally, the bumps 415 (e.g., solder bumps) are formed on the UBM layer 414. The MEMS force sensor 301 can then be mechanically and electrically coupled to the package substrate 416 via the bumps 415. Although the bumps 415 are provided as an example, this disclosure contemplates that copper pillars or any other component capable of electrically connecting the MEMS force sensor 301 to the package substrate 416 can be used. The package substrate 416 can, optionally, be a printed circuit board (PCB) or a flexible printed circuit board (FPCB). PCBs and FPCBs, such as those used in electronics systems as a carrier substrate to electrically and mechanically integrate a functional system together, are known in the art and, therefore, will not be described in further detail herein. As shown in FIG. 4, the conductive pad 106, the UBM layer 414, and the bumps 415 are arranged on the membrane substrate 104 and do not overlap with either the deformable membrane 313 or the mesa 212 of the MEMS force sensor 301.

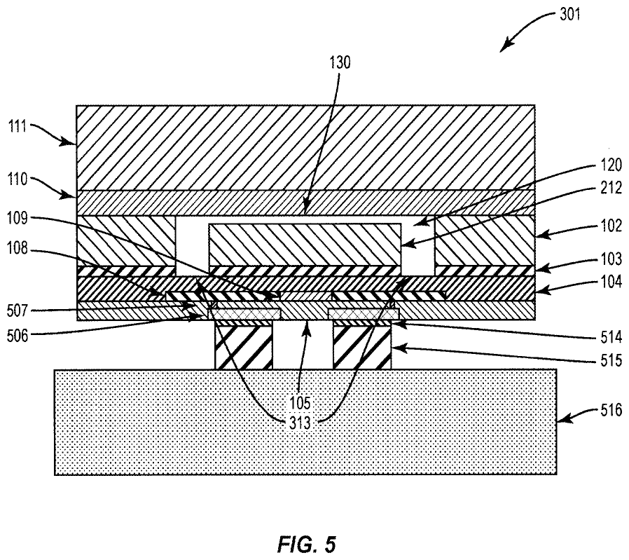

Referring now to FIG. 5, an example MEMS force sensor 301 mounted on a package substrate 516 through solder bumps, where the solder bumps fully overlap with the mesa of the MEMS force sensor 301, is shown. The MEMS force sensor 301 is described in detail above with reference to FIG. 3. It should be understood that the MEMS force sensors shown in FIG. 1 and FIG. 2 can be mounted on a package substrate as described herein. In other words, the MEMS force sensor 301 is used only as an example in FIG. 5.

As shown in FIG. 5, a UBM layer 514 can be formed on each of the conductive pads 106. This disclosure contemplates that the UBM layer 514 can be made of any suitable conductive material, including, but not limited to, aluminum, copper, or gold, for example. The UBM layer 514 is formed in the opening of the protective layer 105 that exposes the conductive pads 106. Additionally, the bumps 515 (e.g., solder bumps) are formed on the UBM layer 514. The MEMS force sensor 301 can then be mechanically and electrically coupled to the package substrate 516 via the bumps 515. Although the bumps 515 are provided as an example, this disclosure contemplates that copper pillars or any other component capable of electrically connecting the MEMS force sensor 301 to the package substrate 516 can be used. The package substrate 516 can, optionally, be a PCB or a FPCB. PCBs and FPCBs, such as those used in electronics systems as a carrier substrate to electrically and mechanically integrate a functional system together, are known in the art and, therefore, will not be described in further detail herein. As shown in FIG. 5, the conductive pad 106, the UBM layer 514, and the bumps 515 are arranged on the membrane substrate 104 and overlap with the mesa 212 of the MEMS force sensor 301.

An example method of manufacturing the MEMS force sensor is now described. It should be understood that the MEMS force sensor can be the MEMS force sensor described above with regard to FIGS. 1-3. The method can include providing a first substrate (e.g., the cavity substrate 102 in FIGS. 1-3), a second substrate (e.g., the membrane substrate 104 in FIGS. 1-3), and an etch stop layer (e.g., the etch stop layer 103 in FIGS. 1-3). As described herein, the etch stop layer can be arranged between the cavity and membrane substrates. A sensing element (e.g., the sensing element 109 in FIGS. 1-3) can be arranged on a surface of the membrane substrate. The sensing element (e.g., the piezoresistive or piezoelectric sensing element) can, optionally, be formed using an implant or deposition process. The formation of sensing elements is known in the art. For example, the formation of sensing elements is described in International Patent Application No. WO2018/148503 to Foughi et al., published Aug. 16, 2018 and entitled “Integrated Digital Force Sensors and Related Methods of Manufacture,” the disclosure of which is incorporated by reference in its entirety. The method can further include etching the cavity substrate, where the etch process removes a portion of the first substrate to form a cavity (e.g., the cavity 120 in FIGS. 1-3) and, optionally, a mesa and a gap (e.g., the mesa 212 and the gap 130 in FIG. 2 and FIG. 3). This disclosure contemplates using etching techniques known in the art. For example, etching processes include, but are not limited to, silicon DRIE, normal RIE, wet chemical etching using KOH, or TMAH, all of which can be used to form the cavity, mesa, and/or gap. In some implementations, the etch process can, optionally, remove a portion of the etch stop layer. For example, the etch stop layer can, optionally, be completely removed, exposing a portion of the membrane substrate (e.g., as shown in FIG. 3). In this implementation, the etch process does not remove a portion of the membrane substrate.

As described herein, the etch stop layer can be configured for precise thickness control of a deformable membrane (e.g., the deformable membrane 113/313 in FIGS. 1-3) defined by at least a portion of the membrane substrate. For example, an etch rate of the etch stop layer can be different than an etch rate of the cavity substrate. For example, the etch rate ratio between an etch rate of the material of the cavity substrate and an etch rate of the material of the etch stop layer can optionally be in the range from 50 to 150. In some implementations, the etch rate ratio is greater than or equal to 50. In some implementations, the etch rate ratio is greater than or equal to 60. In some implementations, the etch rate ratio is greater than or equal to 70. In some implementations, the etch rate ratio is greater than or equal to 80. In some implementations, the etch rate ratio is greater than or equal to 90. In some implementations, the etch rate ratio is greater than or equal to 100. In some implementations, the etch rate ratio is greater than or equal to 110. In some implementations, the etch rate ratio is greater than or equal to 120. In some implementations, the etch rate ratio is greater than or equal to 130. In some implementations, the etch rate ratio is greater than or equal to 140. In some implementations, the etch rate ratio is greater than or equal to 150. This allows the etch stop layer to absorb any non-uniformity introduced by the etch process used to form the cavity, mesa, and/or gap from the cavity substrate. In some implementations, the method can further include bonding a cap substrate (e.g., the cap 111 in FIGS. 1-3) to the cavity substrate, such that the cavity is sealed between the cap substrate and the cavity substrate.

In one implementation, the step of bonding the cap substrate (e.g., the cap 111 in FIGS. 1-3) is performed before the step of forming the sensing element (e.g., the sensing element 109 in FIGS. 1-3). In this implementation, the etch stop layer (e.g., the etch stop layer 103 in FIGS. 1-3), which is optionally formed of S₁O₂ or SiC, is provided on the second substrate (e.g. the membrane substrate 104 in FIGS. 1-3). The membrane substrate has a precisely controlled thickness, as described herein. The first substrate (e.g. the cavity substrate 102 in FIGS. 1-3) is then provided on the etch stop layer. Thereafter, the etching steps are performed, e.g., to form a cavity (e.g., the cavity 120 in FIGS. 1-3) and, optionally, a mesa and a gap (e.g., the mesa 212 and the gap 130 in FIG. 2 and FIG. 3). The cap substrate is then bonded to the cavity substrate such that the cavity is sealed there between. After this bonding, the sensing element can be formed as described herein.

In another implementation, the step of bonding the cap substrate (e.g., the cap 111 in FIGS. 1-3) is performed after the step of forming the sensing element (e.g., the sensing element 109 in FIGS. 1-3). In this implementation, a transfer wafer is used. The sensing element is formed on the second substrate (e.g. the membrane substrate 104 in FIGS. 1-3), which has a precisely controlled thickness, as described herein. The membrane substrate is bonded to the transfer wafer. The etch stop layer (e.g., the etch stop layer 103 in FIGS. 1-3), which is optionally formed of S₁O₂ or SiC, is then provided on the membrane substrate. The first substrate (e.g. the cavity substrate 102 in FIGS. 1-3) is then provided on the etch stop layer. Thereafter, the etching steps are performed, e.g., to form a cavity (e.g., the cavity 120 in FIGS. 1-3) and, optionally, a mesa and a gap (e.g., the mesa 212 and the gap 130 in FIG. 2 and FIG. 3). Using the transfer wafer, the cavity and membrane substrates are carried to the cap substrate for bonding. The cap substrate is then bonded to the cavity substrate such that the cavity is sealed there between. After this bonding, the transfer wafer is removed.

Optionally, the method can further include providing a protective layer (e.g., the protective layer 105 in FIGS. 1-3) arranged on the surface of the membrane substrate and providing a conductive pad (e.g., the conductive pad 106 in FIGS. 1-3) arranged on the protective layer. The sensing element can be electrically coupled to the conductive pad, and the protective layer can at least partially cover one or more of the sensing elements, the surface of the second substrate, and the conductive pad. In some implementations, the method can further include providing a UBM layer (e.g., the UBM layers 414/514 in FIG. 4 and FIG. 5) and a solder bump (e.g., the solder bumps 415/515 in FIG. 4 and FIG. 5) or a copper pillar arranged on the conductive pad. This disclosure contemplates that the UBM layer and the solder bump or the copper pillar can be provided after the formation of the sensor die has been completed. Optionally, the method can include bonding the MEMS force sensor to a package substrate (e.g., the package substrates 416/516 in FIG. 4 and FIG. 5). As described herein, the package substrate can be a PCB or an FPCB. The MEMS force sensor can be mounted on the package substrate using the UBM layer and the solder bump or the copper pillar.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A microelectromechanical system (MEMS) force sensor, comprising:
a sensor die configured to receive an applied force, the sensor die comprising a first substrate and a second substrate, wherein a cavity is formed in the first substrate, and wherein at least a portion of the second substrate defines a deformable membrane;
an etch stop layer arranged between the first substrate and the second substrate;
a sensing element arranged on a surface of the second substrate, wherein the sensing element is configured to convert a strain on the surface of a membrane substrate to an analog electrical signal that is proportional to the strain;
wherein the etch stop layer is configured for precise thickness control of the deformable membrane of the membrane substrate;
wherein an etch rate of the etch stop layer is different than an etch rate of the first substrate; and
wherein an etch rate ratio between the etch rate of the first substrate and the etch rate of the etch stop layer is between 50 and 150.

2. The MEMS force sensor of claim 1, further comprising:
a protective layer arranged on the surface of the second substrate; and
a conductive pad arranged on the protective layer, wherein the sensing element is electrically coupled to the conductive pad, wherein the protective layer at least partially covers the sensing element, the surface of the second substrate, and the conductive pad.

3. The MEMS force sensor of claim 2, further comprising an under bump metal (UBM) layer and a solder bump, wherein the MEMS force sensor is mounted on a package substrate using the UBM layer and the solder bump.

4. The MEMS force sensor of claim 3, wherein the conductive pad, the UBM layer, and the solder bump are overlapping fully with a mesa formed from the first substrate.

5. The MEMS force sensor of claim 3, wherein the conductive pad, the UBM layer, and the solder bump are not overlapping with a mesa formed from the first substrate or the deformable membrane defined by the second substrate.

6. The MEMS force sensor of claim 3, wherein the conductive pad is electrically coupled to the package substrate through the UBM layer and the solder bump.

7. The MEMS force sensor of claim 3, wherein the package substrate is a printed circuit board (PCB) or a flexible printed circuit board (FPCB).

8. The MEMS force sensor of claim 1, further comprising a mesa formed from the first substrate.

9. The MEMS force sensor of claim 1, wherein the etch stop layer covers the deformable membrane of the membrane substrate.

10. The MEMS force sensor of claim 1, wherein the etch stop layer is removed from the deformable membrane of the membrane substrate.

11. The MEMS force sensor of claim 1, wherein the etch stop layer is composed of silicon dioxide, silicon nitride, or sapphire.

12. The MEMS force sensor of claim 1, further comprising a plurality of sensing elements arranged on the surface of the second substrate.

13. The MEMS force sensor of claim 1, wherein the sensing element is a piezoresistive or piezoelectric sensing element.

14. The MEMS force sensor of claim 1, further comprising a cap substrate, wherein the cap substrate is bonded to the first substrate, and wherein the cavity is sealed between the cap substrate and the first substrate.

15. A method of manufacturing a microelectromechanical system (MEMS) force sensor, the method comprising:
providing a first substrate, a second substrate, and an etch stop layer, wherein the etch stop layer is arranged between the first substrate and the second substrate, and wherein a sensing element is arranged on a surface of the second substrate;
etching the first substrate, wherein an etch process removes a portion of the first substrate to form a cavity in the first substrate;
wherein the etch stop layer is configured for precise thickness control of a deformable membrane of a membrane substrate;
wherein an etch rate of the etch stop layer is different than an etch rate of the first substrate; and
wherein an etch rate ratio between the etch rate of the first substrate and the etch rate of the etch stop layer is between 50 and 150.

16. The method of claim 15, wherein the etch process removes a portion of the etch stop layer.

17. The method of claim 15, wherein the etch process does not remove a portion of the second substrate.

18. The method of claim 17, wherein the etch process further forms a mesa in the first substrate.

19. The method of claim 18, further comprising bonding a cap substrate to the first substrate, wherein the cavity is sealed between the cap substrate and the first substrate.

20. The method of claim 15, wherein the MEMS force sensor is provided in an integrated circuit.
